(19) United States
(12) Patent Application Publication
(10) Pub. No.: US 2026/0165130 A1
(43) Pub. Date: Jun. 11, 2026

(54) HEAT DISSPATION DEVICE HAVING DUAL-COUPLED FIN

(71) Applicant: SEMICONDUCTOR COMPONENTS INDUSTRIES, LLC, Scottsdale, AZ (US)

(72) Inventors: Jinseok RYU, Incheon (KR); Jonghwan BAEK, Seoul (KR); Sangyun MA, Bucheon (KR); Hyungil JEON, Namyangju (KR); Roveendra PAUL, Dublin, CA (US)

(73) Assignee: SEMICONDUCTOR COMPONENTS INDUSTRIES, LLC, Scottsdale, AZ (US)

(21) Appl. No.: 19/402,554

(22) Filed: Nov. 26, 2025

Related U.S. Application Data
(60) Provisional application No. 63/729,118, filed on Dec. 6, 2024.

(51) Int. Cl. H01L 23/46; H01L 21/48; H01L 23/00; H01L 25/065

(52) U.S. Cl. CPC H10W 40/40; H10W 40/037; H10W 90/00; H10W 90/736

(57) ABSTRACT

In a general aspect, a heat dissipation device includes a first plate, a second plate, and a fluid channel defined at least in part by the first plate and the second plate. The heat dissipation device includes a plurality of fins disposed in the fluid channel that mechanically join the first plate to the second plate.

### CROSS-REFERENCE TO RELATED APPLICATIONS

This application claims the benefit of U.S. Provisional Application No. 63/729,118, filed on Dec. 6, 2024, which is hereby incorporated by reference in its entirety.

### TECHNICAL FIELD

This description relates to semiconductor package assemblies and, more particularly, to a heat dissipation device having dual-coupled fins.

### BACKGROUND

Semiconductor package assemblies (e.g., semiconductor device power modules) may include substrates that are bonded to thermal dissipation mechanisms (e.g., heat sinks, water jackets, etc.). Mechanical stress due to thermal cycling can weaken the bond between the semiconductor package assemblies and the cooler, leading to poor cooling performance and even detachment.

### SUMMARY

The techniques described herein relate to a heat dissipation device. In a general aspect, a heat dissipation device includes a first plate; a second plate, and a fluid channel defined at least in part by the first plate and the second plate. The heat dissipation device includes a plurality of fins disposed in the fluid channel, the plurality of fins mechanically joining the first plate to the second plate.

In some aspects, the plurality of fins extend from a surface of the first plate, and the heat dissipation device further includes a plurality of metallurgical joints respectively joining the plurality of fins to the second plate.

In some aspects, the plurality of metallurgical joints is one of a plurality of braze joints or a plurality of weld joints.

In some aspects, the plurality of fins and the first plate are integrally formed.

In some aspects, the second plate includes plurality of recesses. The plurality of recesses corresponding with the plurality of fins, which are inserted in the plurality of recesses. In some aspects, the plurality of recesses is a plurality of through-holes.

In some aspects, the heat dissipation device includes a cover plate joined to the first plate.

In some aspects, heat dissipation device includes an inlet port and an outlet port coupled to the fluid channel, the inlet port and the outlet port disposed at opposite ends of the heat dissipation device.

In some aspects, heat dissipation device includes an inlet port and an outlet port coupled to the fluid channel, the inlet port and the outlet port disposed on a bottom surface of the second plate.

In a general aspect, a heat dissipation device includes a first plate including a plurality of recesses. The heat dissipation device includes a second plate including a plurality of fins extending from the second plate and mating with the plurality of recesses. The heat dissipation device includes a fluid channel defined at least in part by the first plate and the second plate, the plurality of fins disposed in the fluid channel.

In some aspects, the heat dissipation device includes a plurality of metallurgical joints that respectively join the plurality of fins to the second plate. The plurality of metallurgical joints can be a plurality of braze joints or a plurality of weld joints.

In some aspects, the first plate is a top plate and the second plate is a bottom plate and the plurality of fins are integrally formed with the bottom plate.

In some aspects, the plurality of recesses is a plurality of a through-holes.

In some aspects, top surfaces of the plurality of fins are substantially coplanar with a surface of the top plate.

In some aspects, the heat dissipation device includes a cover plate coupled to the top plate, the cover plate being configured for attachment to a power module.

In some aspects, the first plate is a bottom plate and the second plate is a top plate and the plurality of fins is integrally formed with the top plate.

In some aspects, the plurality of recesses is a plurality of cavities in a surface of the bottom plate within the fluid channel.

In a general aspect, a method includes coupling a first plate with a second plate such that a plurality of fins extending from the first plate contact the second plate, the first plate and the second plate at least partially defining a fluid channel, the plurality of fins being disposed in the fluid channel. The method also includes forming a metallurgical bond between the plurality of fins and the second plate.

In some aspects, forming the metallurgical bond includes brazing plurality of fins to the second plate. In other aspects, forming the metallurgical bond includes welding plurality of fins to the second plate.

In some aspects, coupling the first plate with the second plate includes mating the plurality of fins with a plurality of recesses in the second plate.

In some aspects, the plurality of recesses is a plurality of through-holes and the method also includes disposing a cover plate on the second plate and forming a metallurgical bond between the cover plate and the second plate and between the cover plate and respective top surfaces of the plurality of fins.

The details of one or more implementations are set forth in the accompanying drawings and the description below. Other features will be apparent from the description and drawings, and from the claims.

### BRIEF DESCRIPTION OF THE DRAWINGS

FIG. 1 is a perspective view of an example cooling assembly in accordance with at least one embodiment of the present disclosure.

FIG. 2 is a sectional front view of a cooling assembly in accordance with at least one embodiment of the present disclosure.

FIG. 3 is a sectional front view of a cooling assembly in accordance with at least one embodiment of the present disclosure.

FIG. 4 is a sectional front view of a cooling assembly in accordance with at least one embodiment of the present disclosure.

FIG. 5 is a sectional front view of a cooling assembly in accordance with at least one embodiment of the present disclosure.

FIG. 6 is a sectional front view of a cooling assembly in accordance with at least one embodiment of the present disclosure.

FIG. 7 schematically illustrates a plan view of a top plate configured with through-holes in accordance with at least one embodiment of the present disclosure.

FIG. 8 schematically illustrates a bottom plate that includes an array of fins in accordance with at least one embodiment of the present disclosure.

FIG. 9 schematically illustrates sectional view of a cooling assembly including a power module coupled to a cooler in accordance with at least one embodiment of the present disclosure.

FIGS. 10A-10C set forth an example process of fabricating a heat dissipation device including a dual-coupled fin array in accordance with at least one embodiment of the present disclosure.

FIGS. 11A-11D set forth another example process of fabricating a heat dissipation device including a dual-coupled fin array in accordance with at least one embodiment of the present disclosure.

FIGS. 12A-12C set forth another example process of fabricating a heat dissipation device including a dual-coupled fin array in accordance with at least one embodiment of the present disclosure.

FIG. 13 sets forth an example method for a heat dissipation device including a dual-coupled fin array in accordance with at least one embodiment of the present disclosure.

In the various drawings, which are not necessarily drawn to scale, like reference symbols may indicate like and/or similar components (elements, structures, etc.) in different views and/or different implementations. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are repeated for context and ease of cross reference between related views. Also, not all like elements in the drawings may be specifically referenced with a reference symbol when multiple instances of an element are illustrated.

### DETAILED DESCRIPTION

A cooler is a thermal dissipation structure configured to remove heat from one or more attached semiconductor devices. The cooler includes a body defining an internal fluid channel through which a coolant (e.g., water, dielectric fluid, or refrigerant) flows between an inlet port and an outlet port. In some implementations, a cooler includes a housing and an attached top plate that define the fluid channel. The cooler can include internal fins, posts, turbulators, or other flow-disrupting structures disposed within the fluid channel to increase internal surface area and improve heat transfer. A mounting surface of the cooler provides a thermally conductive interface to a semiconductor package, power module, or other electronic assembly, enabling heat generated during operation to be efficiently transferred into the coolant. The cooler may be formed from thermally conductive materials such as copper, aluminum, or combinations thereof.

Semiconductor devices such as power modules or integrated circuit packages are coupled to the cooler to dissipate heat generated by those devices. For example, the semiconductor devices can be sintered directly to the cooler using a metal sinter layer (e.g., silver) or by soldering. During thermal cycling, differences in coefficient of thermal expansion between the cooler and the semiconductor package generate stress at the interface. If the cooler lacks sufficient rigidity, warpage causes the cooler surface and/or semiconductor device to deflect, inducing bending stresses into the bond joint (e.g., sinter or solder joint). Such deformation can create localized lifting or separation of the sinter layer, potentially generating micro-cracks, voids, or delamination, which increases thermal resistance and may ultimately cause device failure. Further, deformation of the semiconductor device can cause die cracking or delamination of the die from its substrate.

A cooler's housing includes an upper portion and a lower portion. Typically, the fins extend from one portion of the housing into the fluid channel toward the other portion of the housing. In some cases, the fins contact the other portion of the housing, which can supply some structural rigidity to the cooler. However, a potential area of weakness arises from minute gaps between the end of the fins in the fluid channel and the surface of the opposing housing portion. These microscope gaps reduce the structural rigidity of the heat dissipation device, allowing for slight warpage of the structure. Even a slight amount of warpage can cause damage to the semiconductor package.

To address this, the heat dissipation devices described herein utilize a ‘dual-coupled fin’ architecture. As used herein, ‘dual-coupled fins’ refers to internal fins that are mechanically and thermally secured to both the top and bottom plates of the fluid channel, creating a unified and rigid internal support structure. This dual coupling is achieved in several ways. In some embodiments, fins that are integrally formed with one plate are permanently joined to the opposing plate using a metallurgical bond, such as a braze or weld joint. In some embodiments, the mechanical coupling is achieved by mating the fins with a corresponding array of recesses (e.g., cavities or through-holes) in the opposing plate, into which the fins are inserted. This mechanical interlocking can be further reinforced with a metallurgical bond within the recesses. The primary advantage of any dual-coupled design is a significant increase in the structural rigidity of the entire cooler. By creating a unified, reinforced structure, the fins act as support pillars that prevent the top and bottom plates from deflecting or warping under the mechanical stress of thermal cycling. This enhanced stability preserves the integrity of the bond between the cooler and the attached semiconductor device, ensuring reliable long-term thermal performance and preventing premature device failure.

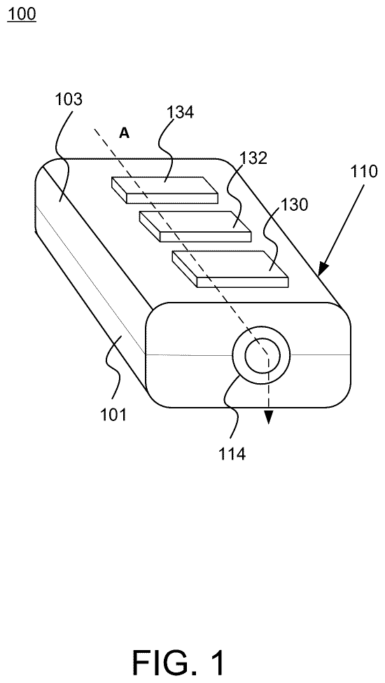

FIG. 1 is a perspective view of an example cooling assembly 100 in accordance with at least one embodiment of the present disclosure. The cooling assembly includes a cooler 110 configured to dissipate heat generated by the semiconductor devices 130, 132, 134 coupled to the cooler 110. The cooler includes a lower housing 101 and an upper housing 103. The lower housing 101 and the upper housing 103 define an internal fluid channel of the cooler 110. A fluid inlet port 114 and a fluid outlet port (not visible) are fluidly coupled to the fluid channel such that a cooling medium enters the cooler 110 through the inlet port 214, passes through the fluid channel, and exits through the outlet port. The assembly 100 enables direct thermal transfer from semiconductor devices 130, 132, 134 into the cooler 110 and into the coolant flowing through the fluid channel.

In various implementations, the cooler 110 can be formed from thermally conductive materials such as copper, aluminum, or combinations thereof. In some implementations, both the upper housing 103 and the lower housing 101 are constructed of aluminum (e.g., constructed only of aluminum). In other implementations, both the upper housing 103 and the bottom plate 201 are constructed of copper (e.g., constructed only of copper). In yet other implementations, the upper housing 103 is copper and the lower housing 101 is aluminum, allowing copper to be located proximate to the semiconductor device to enhance thermal conduction while aluminum reduces overall mass and cost. In other implementations, the upper housing 103 is aluminum and the lower housing 101 is copper, allowing structural rigidity while reducing mass in the upper housing 103. In yet other implementations, at least one of the upper housing 103 and lower housing 101 is a hybrid construction including both aluminum and copper components. For example, the upper housing 103 can include an aluminum body and a copper or nickel-clad copper surface.

In some implementations, in addition being joined by a fin array, the upper housing 103 and lower housing 101 can be joined using brazing, diffusion bonding, adhesive bonding, laser welding, or other suitable joining techniques. In a particular implementation, the upper housing 103 and the lower housing 101 are joined together by friction stir welding. As used herein, friction stir welding (FSW) refers to a solid-state joining process in which a rotating tool is forced against and traversed along a seam between adjacent components. The heat generated by friction plastically deforms the material without melting it, producing a metallurgically bonded joint. FSW provides a low-porosity, high-strength interface and maintains the mechanical and thermal properties of the joined materials. Using friction stir welding to couple the upper housing 103 and the lower housing 101 may be particularly advantageous when the cooler 110 is constructed from dissimilar metals, such as a copper top plate and an aluminum housing, or vice versa. In these implementations, FSW can create mechanical seal capable of withstanding internal coolant pressure while preserving thermal conduction across the interface. Additionally, the solid-state nature of the bonding process can minimize distortion and residual stresses that could otherwise contribute to warpage of the cooler 110.

In some implementations, the upper housing 103 and the lower housing 101 are mechanically fastened together using screws, bolts, or other threaded fasteners. In such embodiments, one or more threaded holes may be formed in the upper housing 103 and/or lower housing 101, and corresponding fasteners are inserted to apply a compressive clamping force along the interface. The mechanical fasteners may be used alone or in combination with other joining techniques, including friction stir welding, brazing, or adhesive bonding, to provide both mechanical strength and fluid sealing performance.

In some implementations, a seal (not shown) is disposed between the upper housing 103 and the lower housing 101 to provide a coolant-tight interface around the fluid channel. In some examples, the lower housing 101 includes a recessed groove formed along at least a portion of its perimeter, and the seal is positioned within the groove prior to joining the components, and described in more detail below. In various implementations, the seal can include an O-ring, gasket, compressible polymer seal, elastomeric ring, or other sealing structure or dispensable sealing material configured to prevent coolant leakage when the upper housing 103 is secured to the lower housing 101. During assembly, the seal is compressed between the upper housing 103 and the lower housing 101 as the components are fastened or welded together.

In some implementations, the semiconductor devices 130, 132, 134 can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In a particular example, a semiconductor die of the semiconductor devices 130, 132, 134 is configured as a switching device for a high voltage DC input power supply (e.g., at least 400 V). In some implementations, one or more semiconductor die can be (e.g., can be a portion of), or can include, a component for an electrical vehicle (EV). In various examples, such semiconductor die can be fabricated using a silicon (Si) substrate or a substrate composed of a wide band gap material such as silicon carbide (SiC) or gallium nitride (GaN) or a gallium arsenide (GaAs).

In some implementations, the semiconductor devices 130, 132, 134 are each a power module that together form a three-phase inverter, with each power module providing a phase of a three-phase output. In some examples, each semiconductor device 130, 132, 134 can include a half-bridge circuit. To generate the three-phase output, each phase can be driven by a half-bridge circuit comprising at least two power switching devices in each semiconductor device 130, 132, 134, with each phase utilizing a high-side and a low-side switch to produce the corresponding phase voltage.

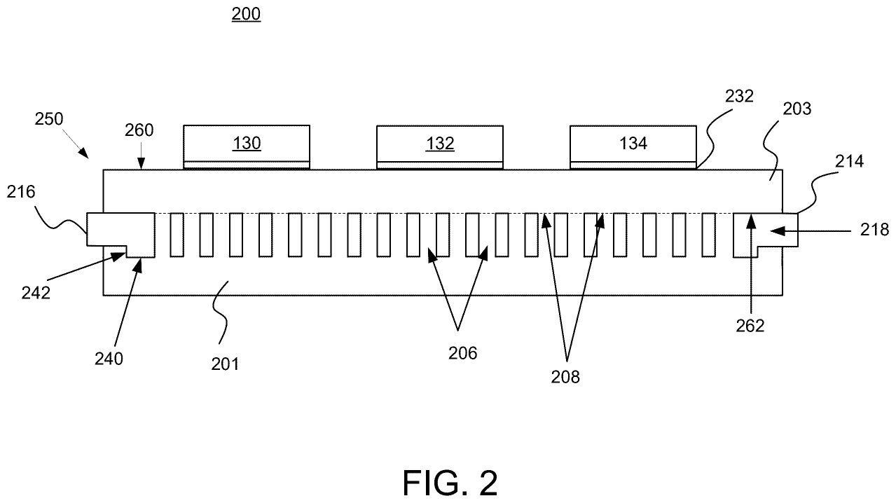

FIG. 2 is a sectional front view of a cooling assembly 200 in accordance with at least one embodiment of the present disclosure. The cooling assembly 200 can be employed to implement the cooling assembly 100 of FIG. 1. For example, FIG. 2 may depict a section of the cooling assembly 100 taken along line A in FIG. 1. The example cooling assembly 200 of FIG. 2 includes a cooler 250 having a bottom plate 201 and a top plate 203. Where the cooler 250 is used to implement the cooler 110 of FIG. 1, the bottom plate 201 can be included in the lower housing 101 of FIG. 1 and the top plate 203 can be included in the upper housing 103 of FIG. 1. The top plate 203 and the bottom plate 201 define, at least in part, an internal fluid channel 218 of the cooler 250. A fluid inlet port 214 and a fluid outlet port 216 are fluidly coupled to the fluid channel 218 such that a cooling medium enters the cooler 250 through the inlet port 214, passes through the fluid channel 218, and exits through the outlet port 216. The assembly 200 shown in FIG. 2 enables direct thermal transfer from semiconductor devices 130, 132, 134 into the cooler 250 and into the coolant flowing through the fluid channel 218.

The top plate 203 includes a top surface 260 to which the semiconductor devices 130, 132, 134 can be coupled and a bottom surface 262 that is opposite the top surface 260. The bottom plate 201 includes a recessed region 240 defined by a wall 242 extending at least partially around a perimeter of the bottom plate 201. The top plate's bottom surface 262, the surface(s) of the wall 242, and the recessed region 240 define, at least in part, the fluid channel 218. The fluid channel 218 can convey various types of coolant. In some examples, the coolant includes water or water-based solutions containing corrosion inhibitors. In other examples, the coolant is a dielectric fluid, allowing the cooler to operate in electrically sensitive environments such as high-voltage power modules. Suitable dielectric fluids include, for example, fluorinated fluids, silicone oils, or hydrocarbon-based dielectric coolants. In some examples, refrigerants may be used in phase-change cooling systems.

In some implementations, as shown in FIG. 2, an array of fins 206 extend into the fluid channel 218 to increase the internal surface area exposed to coolant flow. In the example of FIG. 2, the fins 206 are formed as part of the bottom plate 201 and extend from the floor of the recessed region 240 of the bottom plate 201 into the fluid channel 218. In some implementations, the fins 206 are integrally formed with the bottom plate 201, in that the fins 206 are unitary with the bottom plate 201 and form a monolithic structure. The term ‘integrally formed’ as used can refer to the bottom plate 201 and the fins 206 being produced as a single piece, such as through extrusion, die casting, machining from a solid block (e.g., milling or computer numerical control (CNC)), or skiving. As a result, each fin 206 is continuous with the bottom plate 201 and lacks any joint, seam, bond line, or interface that might otherwise occur if the fins 206 were separately attached.

The fins 206 may have various geometries, including but not limited to straight fins, pin fins, louvered fins, tapered fins, or curved fins configured to induce turbulence or directional flow. In some implementations, the fins 206 extend between the top plate 203 and the bottom plate 201 to mechanically couple opposing walls of the fluid channel 218 and increase the structural rigidity of the cooler 250. Increasing fin height, thickness, or density may further increase rigidity and reduce warpage of the cooler 250.

While the fins 206 are integrally formed with the bottom plate 201, the fins 206 are coupled to the top plate 203 by metallurgical bonds 208. For example, top surfaces of the fins 206 can be metallurgically bonded to the bottom surface 262 of the top plate 203. In some embodiments, the fins 206 are joined to the top plate 203 through a brazing process. For example, the fins 206 can be positioned against the bottom surface 262 of the top plate 203 such that each fin 206 contacts a corresponding bonding region on the bottom surface 262. A brazing material is applied at least at the interface between each fin 206 and the bonding region. The cooler 250 is then heated to a temperature sufficient to melt the brazing material while maintaining the top plate 203 and the fins 206 below their melting temperatures. Upon reaching the brazing temperature, the molten brazing material wets the surface of the top plate 203 and the fins, thereby forming a metallurgical bond. The assembly is subsequently cooled, allowing the brazing material to solidify to produce a joint securing each fin to the heat sink. In various implementations, the brazing material may be provided as a preform, a wire, a paste, a clad layer, or a plated coating. In various implementations, the brazing material can include silver-based alloys, copper-based alloys, aluminum-based alloys, nickel-based alloys, gold-based alloys, and the like.

In some implementations, the fins 206 are joined to the top plate 203 through a welding process. The welding process can include positioning each fin 206 at a corresponding bonding region on the top plate 203. The fins 206 can be held in contact with the top plate 203 using a fixture, magnetic alignment tools, or gravity-assisted placement. Once positioned, a welding operation is performed to fuse each fin 206 to the top plate 203. The welding may be carried out using any suitable welding technique, including resistance welding, laser welding, electron-beam welding, micro-arc welding, and so on. During welding, localized heat is applied to at least a portion of the interface between each fin 206 and the top plate 203 to raise the interface to a temperature sufficient to melt at least one of the fin material and the material of top plate 203, thereby forming a fused weld region. The weld region is allowed to solidify, creating a metallurgical joint that secures the fin to top plate 203.

In the example of FIG. 2, the semiconductor devices 130, 132, 134 are coupled to the top surface of the cooler 250, specifically, the top plate 203. The semiconductor devices 130, 132, 134 can include a semiconductor package, a power module, a multi-die package, or a bare semiconductor die. In some implementations (as shown in FIG. 2), a bond layer 232 is disposed between the semiconductor devices 130, 132, 134 and the cooler 250 and provides both thermal conduction and mechanical attachment. The bond layer 232 may include solder, sintered metal (e.g., silver sinter paste), conductive adhesive, transient liquid phase bonding material, or other attachment materials. Additionally or alternatively, the semiconductor devices 130, 132, 134 can be mechanically fastened to the cooler 250 using screws, bolts, clamps, and the like.

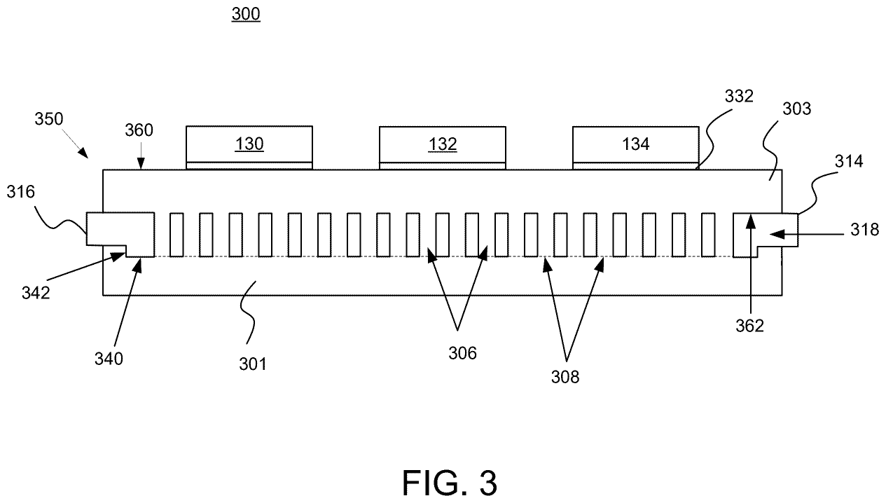

FIG. 3 is a sectional front view of a cooling assembly 300 in accordance with at least one embodiment of the present disclosure. The cooling assembly 300 can be employed to implement the cooling assembly 100 of FIG. 1. For example, FIG. 3 may depict a section of the cooling assembly 100 taken along line A in FIG. 1. The example cooling assembly 300 of FIG. 3 includes a cooler 350 having a bottom plate 301 and a top plate 303. Where the cooler 350 is used to implement the cooler 110 of FIG. 1, the bottom plate 301 can be included in the lower housing 101 of FIG. 1 and the top plate 303 can be included in the upper housing 103 of FIG. 1. The top plate 303 and the bottom plate 301 define, at least in part, an internal fluid channel 318 of the cooler 350. A fluid inlet port 314 and a fluid outlet port 316 are fluidly coupled to the fluid channel 318 such that a cooling medium enters the cooler 350 through the inlet port 314, passes through the fluid channel 318, and exits through the outlet port 316. The assembly 300 shown in FIG. 3 enables direct thermal transfer from the semiconductor devices 130, 132, 134 into the cooler 350 and into the coolant flowing through the fluid channel 318.

The top plate 303 includes a top surface 360 to which the semiconductor devices 130, 132, 134 can be coupled and a bottom surface 362 that is opposite the top surface 360. The bottom plate 301 includes a recessed region 340 defined by a wall 342 extending at least partially around a perimeter of the bottom plate 301. The top plate's bottom surface 362, the surface(s) of the wall 342, and the recessed region 340 define, at least in part, the fluid channel 318. The fluid channel 318 can convey various types of coolant. In some examples, the coolant includes water or water-based solutions containing corrosion inhibitors. In other examples, the coolant is a dielectric fluid, allowing the cooler to operate in electrically sensitive environments such as high-voltage power modules. Suitable dielectric fluids include, for example, fluorinated fluids, silicone oils, or hydrocarbon-based dielectric coolants. In some examples, refrigerants may be used in phase-change cooling systems.

In some implementations, as shown in FIG. 3, an array of fins 306 extend into the fluid channel 318 to increase the internal surface area exposed to coolant flow. In the example of FIG. 3, the fins 306 are formed as part of the top plate 303 and extend from the bottom surface 362 of the top plate 303 into the fluid channel 318. In some implementations, the fins 306 are integrally formed with the top plate 303, in that the fins 306 are unitary with the top plate 303 and form a monolithic structure. The term ‘integrally formed’ as used can refer to the top plate 303 and the fins 306 being produced as a single piece, such as through extrusion, die casting, machining from a solid block (e.g., milling or computer numerical control (CNC)), or skiving. As a result, each fin 306 is continuous with the top plate 303 and lacks any joint, seam, bond line, or interface that might otherwise occur if the fins 306 were separately attached.

The fins 306 may have various geometries, including but not limited to straight fins, pin fins, louvered fins, tapered fins, or curved fins configured to induce turbulence or directional flow. In some implementations, the fins 306 extend between the top plate 303 and the bottom plate 301 to mechanically couple opposing walls of the fluid channel 318 and increase the structural rigidity of the cooler 350. Increasing fin height, thickness, or density may further increase rigidity and reduce warpage of the cooler 350.

While the fins 306 are integrally formed with the top plate 303, the fins 306 are coupled to the bottom plate 301 by metallurgical bonds 308. For example, top surfaces of the fins 306 can be metallurgically bonded to the recessed region 340 of the bottom plate 301. In some embodiments, the fins 306 are joined to the bottom plate 301 through a brazing process. For example, the fins 306 can be positioned against the bottom surface 362 of the bottom plate 301 such that each fin 306 contacts a corresponding bonding region on the bottom plate 301. A brazing material is applied at least at the interface between each fin 306 and the bonding region. The cooler 350 is then heated to a temperature sufficient to melt the brazing material while maintaining the top plate 303, bottom plate, 301, and the fins 306 below their melting temperatures. Upon reaching the brazing temperature, the molten brazing material wets the surface of the bottom plate 301 and the fins, thereby forming a metallurgical bond. The assembly is subsequently cooled, allowing the brazing material to solidify to produce a joint securing each fin to the heat sink. In various implementations, the brazing material may be provided as a preform, a wire, a paste, a clad layer, or a plated coating. In various implementations, the brazing material can include silver-based alloys, copper-based alloys, aluminum-based alloys, nickel-based alloys, gold-based alloys, and the like.

In some implementations, the fins 306 are joined to the bottom plate 301 through a welding process. The welding process can include positioning each fin 306 at a corresponding bonding region on the bottom plate 301. The fins 306 can be held in contact with the bottom plate 301 using a fixture, magnetic alignment tools, or gravity-assisted placement. Once positioned, a welding operation is performed to fuse each fin 306 to the bottom plate 301. The welding may be carried out using any suitable welding technique, including resistance welding, laser welding, electron-beam welding, micro-arc welding, and so on. During welding, localized heat is applied to at least a portion of the interface between each fin 306 and the bottom plate 301 to raise the interface to a temperature sufficient to melt at least one of the fin material and the material of bottom plate 301, thereby forming a fused weld region. The weld region is allowed to solidify, creating a metallurgical joint that secures the fin to the bottom plate 301.

In the example of FIG. 3, the semiconductor devices 130, 132, 134 are coupled to the top surface of the cooler 350, specifically, the top plate 303. The semiconductor devices 130, 132, 134 can include a semiconductor package, a power module, a multi-die package, or a bare semiconductor die. In some implementations (as shown in FIG. 3), a bond layer 332 is disposed between the semiconductor devices 130, 132, 134 and the cooler 350 and provides both thermal conduction and mechanical attachment. The bond layer 332 may include solder, sintered metal (e.g., silver sinter paste), conductive adhesive, transient liquid phase bonding material, or other attachment materials. Additionally or alternatively, the semiconductor devices 130, 132, 134 can be mechanically fastened to the cooler 350 using screws, bolts, clamps, and the like.

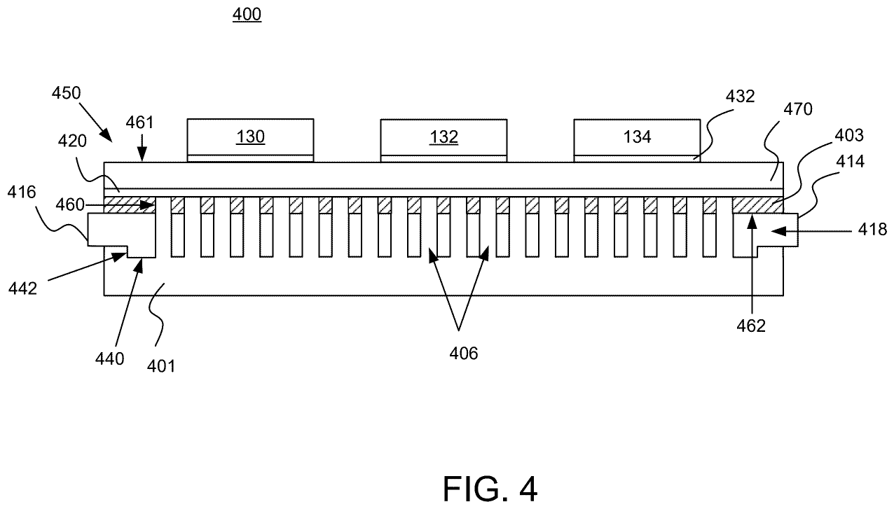

FIG. 4 is a sectional front view of a cooling assembly 400 in accordance with at least one embodiment of the present disclosure. The cooling assembly 400 can be employed to implement the cooling assembly 100 of FIG. 1. For example, FIG. 4 may depict a section of the cooling assembly 100 taken along line A in FIG. 1. The example cooling assembly 400 of FIG. 4 includes a cooler 450 having a bottom plate 401 and a top plate 403. Where the cooler 450 is used to implement the cooler 110 of FIG. 1, the bottom plate 401 can be included in the lower housing 101 of FIG. 1 and the top plate 403 can be included in the upper housing 103 of FIG. 1. The top plate 403 and the bottom plate 401 define, at least in part, an internal fluid channel 418 of the cooler 450. A fluid inlet port 414 and a fluid outlet port 416 are fluidly coupled to the fluid channel 418 such that a cooling medium enters the cooler 450 through the inlet port 414, passes through the fluid channel 418, and exits through the outlet port 416. The fluid channel 418 can convey various types of coolant. In some examples, the coolant includes water or water-based solutions containing corrosion inhibitors. In other examples, the coolant is a dielectric fluid, allowing the cooler to operate in electrically sensitive environments such as high-voltage power modules. Suitable dielectric fluids include, for example, fluorinated fluids, silicone oils, or hydrocarbon-based dielectric coolants. In some examples, refrigerants may be used in phase-change cooling systems. The assembly 400 shown in FIG. 4 enables direct thermal transfer from the semiconductor devices 130, 132, 134 into the cooler 450 and into the coolant flowing through the fluid channel 418.

The bottom plate 401 includes a recessed region 440 defined by a wall 442 extending at least partially around a perimeter of the bottom plate 401. In some implementations, as shown in FIG. 4, an array of fins 406 extend into the fluid channel 418 to increase the internal surface area exposed to coolant flow. In the example of FIG. 4, the fins 406 are formed as part of the bottom plate 401 and extend from the floor of the recessed region 440 of the bottom plate 401 into the fluid channel 418. In some implementations, the fins 406 are integrally formed with the bottom plate 401, in that the fins 406 are unitary with the bottom plate 401 and form a monolithic structure. The term ‘integrally formed’ as used can refer to the bottom plate 401 and the fins 406 being produced as a single piece, such as through extrusion, die casting, machining from a solid block (e.g., milling or computer numerical control (CNC)), or skiving. As a result, each fin 406 is continuous with the bottom plate 401 and lacks any joint, seam, bond line, or interface that might otherwise occur if the fins 406 were separately attached.

The fins 406 may have various geometries, including but not limited to straight fins, pin fins, louvered fins, tapered fins, or curved fins configured to induce turbulence or directional flow. In some implementations, the fins 406 extend between the top plate 403 and the bottom plate 401 to mechanically couple opposing walls of the fluid channel 418 and increase the structural rigidity of the cooler 450. Increasing fin height, thickness, or density may further increase rigidity and reduce warpage of the cooler 450.

The top plate 403 is configured with an array of recesses 460 that mate with the array of fins 406. In various implementations, each recess 460 may be implemented as a through-hole that extends entirely through the thickness of the top plate 403, or as a cavity that extends only partially through the thickness of the top plate 403. The recesses 460 may be sized and shaped to receive the fins 406 and can be configured with a geometry corresponding to the geometry of the fins 406. The top plate 403 can include any number of recesses 460 distributed across its surface and the recesses 460 can be arranged in a pattern that corresponds with a pattern of the fins 406. The top plate 403 having the recesses 460 can be produced using any suitable fabrication technique, such as drilling, milling, punching, laser machining, casting, or molding.

In some implementations, the recesses 460 are through-holes that extend from one surface of the top plate 403 to the opposite surface. In such implementations, the top plate 403 is mounted on the fins such that ends of the fins 406 are inserted into the through-holes. For example, the fins 406 are inserted into a bottom surface 462 of the top plate 403 that faces the bottom plate 401, such that top surfaces of the fins 406 are exposed on the top surface 461 of the top plate 403. In some examples, the top surfaces of the fins 406 are coplanar with the top surface 461 of the top plate 403. In other examples, the ends of the fins 406 are partially inserted into the through-holes such that the top surfaces of the fins 406 are not coplanar such as being recessed relative to the top surface 461 of the top plate. In some examples, insertion of the fins 406 into the recesses 460 (e.g., through-holes) mechanically couples the fins 406, and thus the bottom plate 401, to the top plate 403 via frictional force.

In other implementations, the recesses 460 are cavities or, in other words, indentations that extend only partially through a thickness of the top plate 403. In such implementations, the top plate 403 is mounted on the fins such that ends of the fins 406 are inserted into and received by the cavities. For example, the cavities are disposed on a bottom surface 462 of the top plate 403 that faces the bottom plate 401. In these implementations, top surfaces of the fins 406 are not exposed on the top surface 461 of the top plate. In some examples, insertion of the fins 406 into the recesses 460 (e.g., through-holes) mechanically couples the fins 406, and thus the bottom plate 401, to the top plate 403 via frictional force.

The top plate's bottom surface 462, the surface(s) of the wall 442, and the recessed region 440 (e.g., the floor) define, at least in part, the fluid channel 418.

In some implementations, the fins 406 are coupled to the top plate 403 by metallurgical bonds. For example, ends of the fins 406 can be metallurgically bonded in the recesses 460 of the top plate 403. In some embodiments, the fins 406 are joined to the top plate 403 through a brazing process. For example, the fins 406 can be positioned in the recesses 460 the top plate 403 A brazing material is applied at least at the interface between each fin 406 and the recess. The cooler 450 is then heated to a temperature sufficient to melt the brazing material while maintaining the top plate 403 and the fins 406 below their melting temperatures, thereby forming a metallurgical bond. The assembly is subsequently cooled, allowing the brazing material to solidify to produce a joint securing each fin to the heat sink. In various implementations, the brazing material may be provided as a preform, a wire, a paste, a clad layer, or a plated coating. In various implementations, the brazing material can include silver-based alloys, copper-based alloys, aluminum-based alloys, nickel-based alloys, gold-based alloys, and the like.

In some implementations, the fins 406 are joined to the top plate 403 through a welding process. The welding process can include positioning each fin 406 at a corresponding recess 460 in the top plate 403. Once positioned, a welding operation is performed to fuse each fin 406 to the top plate 403. The welding may be carried out using any suitable welding technique, including resistance welding, laser welding, electron-beam welding, micro-arc welding, and so on.

In some implementations, as shown in FIG. 4, the cooler 450 includes a cover plate 470 coupled to the top surface 461 of the top plate 403. In some implementations, where the recesses 460 are through-holes, the cover plate 470 can be coupled to the top surface 461 of the top plate 403 and also coupled to the top surfaces of the fins 406. In some implementations, the cover plate is coupled to the top surface 461 of the top plate 403 and also coupled to the top surfaces of the fins 406 via a bond layer 420. The bond layer 420 can include a thermally conductive adhesive such as silver filled epoxy, polymers, solder or sinter material, brazing material, and the like. In some examples, the cover plate 470 is coupled with the plate 403 and the upper surfaces of the fins 406 using a layer of brazing material. That is, in some implementations, the cover plate 470 can be brazed to the top plate 403 and the upper surfaces of the fins 406. In some implementations, the cover plate 470 can be coupled to the upper surfaces of the fins 406 and the top plate 403 using a solid-state joining process, such as friction stir welding (FSW). In various examples, the cover plate 470 can be composed of aluminum, copper, nickel-clad copper, and so forth. In some implementations, the cover plate 470 is composed of a material that is different from the material composition of the top plate 403. The use of copper for the cover plate 470 can increase thermal conductivity of the cooler 450, e.g., as compared to coolers that include only aluminum.

In the example of FIG. 4, the semiconductor devices 130, 132, 134 are coupled to the top surface of the cover plate 470. The semiconductor devices 130, 132, 134 can include a semiconductor package, a power module, a multi-die package, or a bare semiconductor die. In some implementations (as shown in FIG. 4), a bond layer 432 is disposed between the semiconductor devices 130, 132, 134 and the cooler 450 and provides both thermal conduction and mechanical attachment. The bond layer 432 may include solder, sintered metal (e.g., silver sinter paste), conductive adhesive, transient liquid phase bonding material, or other attachment materials. Additionally or alternatively, the semiconductor devices 130, 132, 134 can be mechanically fastened to the cooler 450 using screws, bolts, clamps, and the like.

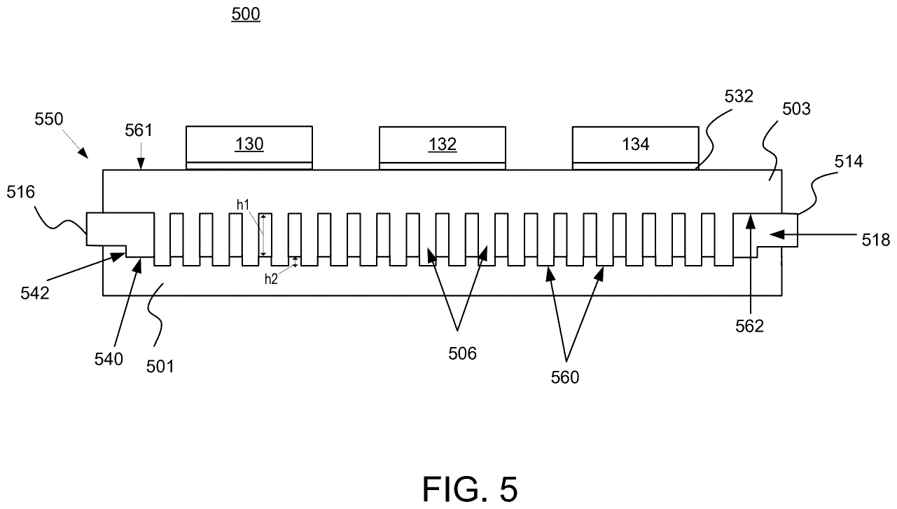

FIG. 5 is a sectional front view of a cooling assembly 500 in accordance with at least one embodiment of the present disclosure. The cooling assembly 500 can be employed to implement the cooling assembly 100 of FIG. 1. For example, FIG. 5 may depict a section of the cooling assembly 100 taken along line A in FIG. 1. The example cooling assembly 500 of FIG. 5 includes a cooler 550 having a bottom plate 501 and a top plate 503. Where the cooler 550 is used to implement the cooler 110 of FIG. 1, the bottom plate 501 can be included in the lower housing 101 of FIG. 1 and the top plate 503 can be included in the upper housing 103 of FIG. 1. The top plate 503 and the bottom plate 501 define, at least in part, an internal fluid channel 518 of the cooler 550. A fluid inlet port 514 and a fluid outlet port 516 are fluidly coupled to the fluid channel 518 such that a cooling medium enters the cooler 550 through the inlet port 514, passes through the fluid channel 518, and exits through the outlet port 516. The assembly 500 shown in FIG. 5 enables direct thermal transfer from the semiconductor devices 130, 132, 134 into the cooler 550 and into coolant flowing through the fluid channel 518.

The top plate 503 includes a top surface 561 to which the semiconductor devices 130, 132, 134 can be coupled and a bottom surface 562 that is opposite the top surface 561. The bottom plate 501 includes a recessed region 540 defined by a wall 542 extending at least partially around a perimeter of the bottom plate 501 and a floor that includes a portion of the top surface of the bottom plate 201. The top plate's bottom surface 562, the surface(s) of the wall 542, and the recessed region 540 define, at least in part, the fluid channel 518. The fluid channel 518 can convey various types of coolant.

In some implementations, as shown in FIG. 5, an array of fins 506 extend into the fluid channel 518 to increase the internal surface area exposed to coolant flow. In the example of FIG. 5, the fins 506 are formed as part of the top plate 503 and extend from the bottom surface 562 of the top plate 503 into the fluid channel 518. In some implementations, the fins 506 are integrally formed with the top plate 503, in that the fins 506 are unitary with the top plate 503 and form a monolithic structure.

The fins 506 may have various geometries, including but not limited to straight fins, fin fins, louvered fins, tapered fins, or curved fins configured to induce turbulence or directional flow. In some implementations, the fins 506 extend between the top plate 503 and the bottom plate 501 to mechanically couple opposing walls of the fluid channel 518 and increase the structural rigidity of the cooler 550. Increasing fin height, thickness, or density may further increase rigidity and reduce warpage of the cooler 550.

The bottom plate 501 is configured with an array of recesses that mate with the array of fins 506. In various implementations, each recess may be implemented as a cavity 560 that extends only partially through the thickness of the bottom plate 501. The cavities 560 may be sized and shaped to receive the fins 506 and can be configured with a geometry corresponding to the geometry of the fins 506. The bottom plate 501 can include any number of cavities 560 distributed across its surface and the cavities 560 can be arranged in a pattern that corresponds with a pattern of the fins 506. The bottom plate 501 having the cavities 560 can be produced using any suitable fabrication technique, such as drilling, milling, punching, laser machining, casting, or molding. As shown in FIG. 5, the fins 506 have a portion that is dispose in the fluid channel 518 having a height h1 and a portion disposed inside the cavity 560 having a height h2. The height h1 is greater than the height h2, such that most of the fin 506 is exposed to the fluid channel while only a portion is disposed in the cavity 560.

In some implementations, the fins 506 are mounted on the bottom plate 501 such that ends of the fins 506 are inserted into and received by the cavities. For example, the cavities are disposed on a floor of the recessed region 540 of the bottom plate 501 that faces the top plate 503. In some examples, insertion of the fins 506 into the cavities 560 mechanically couples the fins 506, and thus the top plate 503, to the bottom plate 501 via frictional force.

In some implementations, the fins 506 are coupled to the bottom plate 501 by metallurgical bonds. For example, ends of the fins 506 can be metallurgically bonded to the cavities 560 in the recessed region 540 of the bottom plate 501. In some embodiments, the fins 506 are joined to the bottom plate 501 through a brazing process. For example, the fins 506 can be positioned in the cavities 560 of the bottom plate 501 such that each fin 506 is inserted into a corresponding cavity 560. A brazing material can be applied at least at the interface between each fin 506 and the cavity 560. The cooler 550 is then heated to a temperature sufficient to melt the brazing material while maintaining the top plate 503, bottom plate, 501, and the fins 506 below their melting temperatures, thereby forming a metallurgical bond. The assembly is subsequently cooled, allowing the brazing material to solidify to produce a joint securing each fin to the heat sink. In various implementations, the brazing material may be provided as a preform, a wire, a paste, a clad layer, or a plated coating. In various implementations, the brazing material can include silver-based alloys, copper-based alloys, aluminum-based alloys, nickel-based alloys, gold-based alloys, and the like.

In some implementations, the fins 506 are joined to the bottom plate 501 through a welding process. The welding process can include positioning each fin 506 at a corresponding bonding region on the bottom plate 501. The fins 506 can be held in contact with the bottom plate 501 using a fixture, magnetic alignment tools, or gravity-assisted placement. Once positioned, a welding operation is performed to fuse each fin 506 to the bottom plate 501. The welding may be carried out using any suitable welding technique, including resistance welding, laser welding, electron-beam welding, micro-arc welding, and so on. During welding, localized heat is applied to at least a portion of the interface between each fin 506 and the bottom plate 501 to raise the interface to a temperature sufficient to melt at least one of the fin material and the material of bottom plate 501, thereby forming a fused weld region. The weld region is allowed to solidify, creating a metallurgical joint that secures the fin to the bottom plate 501.

In the example of FIG. 5, the semiconductor devices 130, 132, 134 are coupled to the top surface of the cooler 550, specifically, the top plate 503. The semiconductor devices 130, 132, 134 can include a semiconductor package, a power module, a multi-die package, or a bare semiconductor die. In some implementations (as shown in FIG. 5), a bond layer 532 is disposed between the semiconductor devices 130, 132, 134 and the cooler 550 and provides both thermal conduction and mechanical attachment. The bond layer 532 may include solder, sintered metal (e.g., silver sinter paste), conductive adhesive, transient liquid phase bonding material, or other attachment materials. Additionally or alternatively, the semiconductor devices 130, 132, 134 can be mechanically fastened to the cooler 550 using screws, bolts, clamps, and the like.

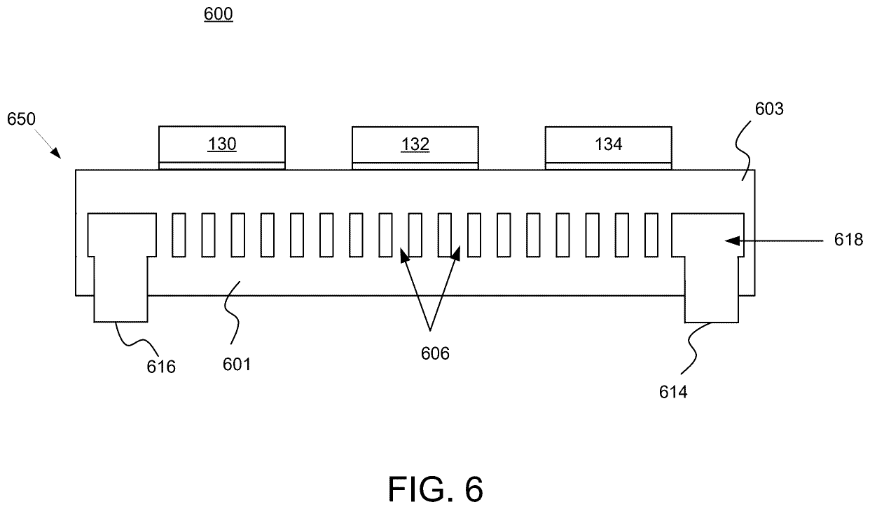

FIG. 6 is a sectional front view of a cooling assembly 600 in accordance with at least one embodiment of the present disclosure. The example cooling assembly 600 of FIG. 6 includes a cooler 650 having a bottom plate 601 and a top plate 603 that are joined together by an array of fins 606. The cooler 650 can be constructed in the same manner as the cooler 250 of FIG. 2, the cooler 350 of FIG. 3, the cooler 450 of FIG. 4, and/or the cooler 550 of FIG. 5. That is, the fins 606 can be integrally formed with the bottom plate 601 and metallurgically bonded to the top plate 603; or, the fins 606 can be integrally formed with the top plate 603 and metallurgically bonded to the bottom plate 601. The bottom plate 601 or the top plate 603 can include recesses with which the fins 606 mate.

The cooler 650 differs from the coolers of FIGS. 6-5 in that the cooler 650 includes a fluid inlet port 614 and a fluid outlet port 616 disposed on a bottom side of the bottom plate 601. For example, the fluid inlet port 614 can be referred to as being disposed on a bottom surface of the cooler 650 at (near, proximate, etc.) a proximal end of the cooler 650, while the fluid outlet port 616 can be referred to as being disposed on a bottom surface of the cooler 650 at (near, proximate, etc.) a distal end of the cooler 650. In some implementations, other configurations for fluid inlets and outlets can be used (e.g., inlets and outlets disposed on a top surface of the cooler, or an inlet disposed on a top surface and an outlet disposed on a bottom surface, or vice versa).

The fluid inlet port 614 and fluid outlet port 616 are fluidly coupled to a fluid channel 618 of the cooler such that a cooling medium enters the cooler 650 through the inlet port 614, passes through the fluid channel 618, and exits through the outlet port 616. The assembly 600 shown in FIG. 6 enables direct thermal transfer from the semiconductor devices 130, 132, 134 into the cooler 650 and into the coolant flowing through the fluid channel 618.

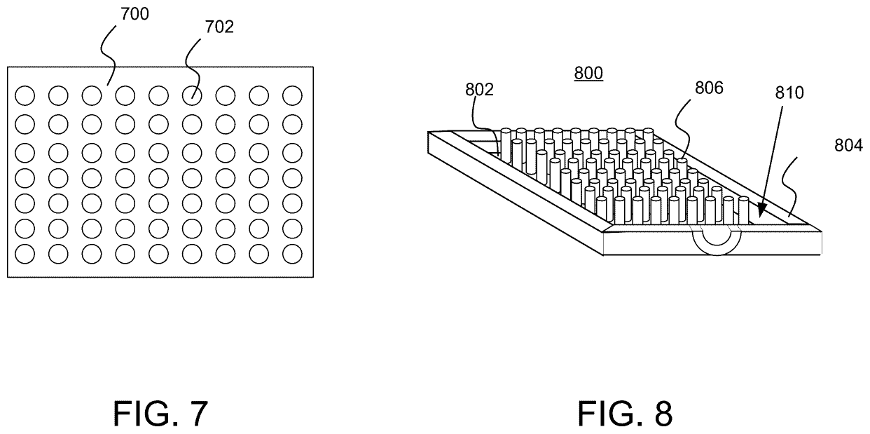

For further explanation, FIG. 7 schematically illustrates a plan view of a top plate 700 configured with through-holes 702 in accordance with at least one embodiment of the present disclosure. The top plate 700 having the through-holes 702 can be produced using suitable fabrication techniques such as drilling, milling, punching, laser machining, casting, or molding. In some examples, the top plate 700 can be used to implement the top plate 403 of FIG. 4. It will be appreciated that FIG. 7 is illustrative and that the top plate 700 can include any number of through-holes, which can be arranged in any pattern that corresponds with a pattern of a fin array. Although the through-holes 702 are depicted as having a circular or cylindrical geometry, it will be appreciated that the through-holes 702 can have other geometries such as the fin geometries discussed above.

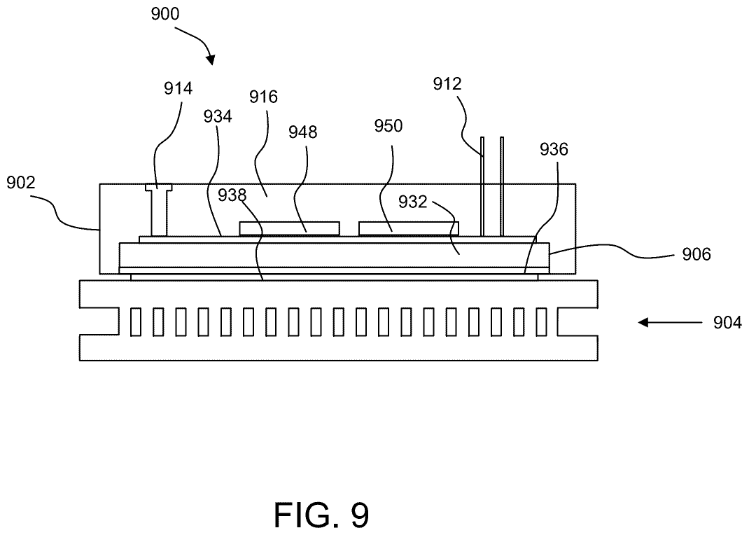

For further explanation, FIG. 8 schematically illustrates a bottom plate 800 that includes an array of fins 806, which are monolithically and integrally formed as part of the bottom plate 800. The fins 806 extend orthogonally from the top surface 802 of the bottom plate 800. In some implementations, the bottom plate 800 includes a wall 804 defining a recessed region 810 of the bottom plate 800, where a floor of the recessed region 810 includes a portion of the top surface 802 of the bottom plate 800. In various implementations, the bottom plate 800 can implement the bottom plate 201 of FIG. 2 and/or the bottom plate 401 of IFG. 4. Although the fins 806 are depicted as having a cylindrical geometry, it will be appreciated that the fins 806 can have other geometries such as those discussed above. It will be appreciated that FIG. 8 is illustrative and that the bottom plate 800 can include any number of fins, which can be arranged in various other patterns.

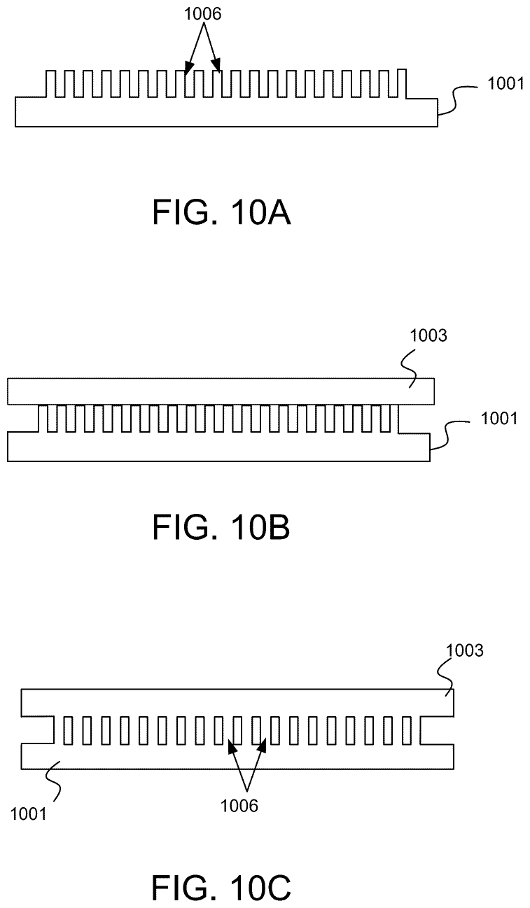

For further illustration, FIG. 9 schematically illustrates sectional view of a cooling assembly 900 including a power module 902 coupled a cooler 904. For example, the cooler 904 of FIG. 9 can be implemented by the cooler 110 of FIG. 1, the cooler 250 of FIG. 2, the cooler 350 of FIG. 3, the cooler 450 of FIG. 4, the cooler 550 of FIG. 5, and/or the cooler 650 of FIG. FIG. 6. The power module 902 can be implemented as the semiconductor devices 130, 132, 134, although only a single power module 902 is depicted for ease of explanation.

In the example of FIG. 9, the power module 902 includes one or more semiconductor dies 948, 950. In some implementations, a semiconductor die 948, 950 can include a power device for conditioning, converting, or switching a power supply. In various examples, the semiconductor die 948, 950 can implement an IGBT power electronics device, a MOSFET power electronics device, or other electronics devices suitable for controlled switching in high voltage applications. In a particular example, the semiconductor die 948, 950 is configured as a switching device for a high voltage DC input power supply (e.g., at least 1000 V). In various examples, the semiconductor die 948, 950 can be fabricated using silicon, silicon carbide, gallium nitride, gallium arsenide, a silicon-silicon carbide hybrid material, and other suitable semiconductor die materials that will be recognized based on the present disclosure.

At least one semiconductor die 948 is mounted on a substrate 906. For example, the semiconductor die 948 can be coupled to substrate by a thermally conductive adhesive such as solder, thermal interface material, phase change material, sinter material, and so forth. In some implementations, the substrate 906 is a DBM substrate. In some implementations, the DBM substrate (e.g., direct bonded copper (DBC)) includes an insulating layer 932 disposed between a first metal layer 934 (e.g., a top metal layer) and a second metal layer 936 (e.g., a bottom metal layer). The insulating layer 932 can be, for example, a ceramic layer. In some implementations, the insulating layer 932 can be or can include, for example, a ceramic material such as alumina (Al₂O₃) or aluminum nitride (AlN)). In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process (e.g., diffusion bonding).

In some implementations, the first metal layer 934 of the DBM substrate 906 can be or can include a patterned metal layer including one or more electrically conductive traces. In some implementations, the first metal layer 934 can be or can include a patterned layer configured to form one or more electrical circuits, one or more conductive blind and/or through vias, and/or so forth. In some examples, the first metal layer 934 includes one or more circuit portions, contacts, pads, and so forth.

In the example of FIG. 9, a bottom surface of the bottom metal layer 936 of the substrate 906 corresponds to a surface SS1 of the substrate 906 that is coupled to the cooler 904 via a thermally conductive adhesive material 938 via a bonding process such as, for example, soldering or sintering. In these implementations, the conductive adhesive material 938 can be a solder material, a sintering material (e.g., silver or copper), an epoxy material (e.g., silver filled epoxy), a thermal interface material, and so forth.

In some implementations, as shown in FIG. 9, the power module 902 includes one or more signal pins 912 extending in a direction orthogonal to the patterned first metal layer 934 on top surface of the substrate 906. In some examples, the signal pins 912 can be inserted (e.g., press-fit) into the substrate 906. For example, the signal pins 912 can be press-fit into plated openings in the substrate 906, where the plated openings can be electrically connected with respective portions of the patterned first metal layer 934 of the substrate 906. The signal pins 912 provide an external electrical interconnect for the power module 902.

In some implementations, the power module 902 includes one or more input power terminals 914 provide an external electrical interconnect for the power module 902 to receive an input power supply, such as a DC power supply. For example, the input power terminals may be located on a top surface of the power module 902. In these implementations, the power module 902 also includes one or more output power terminals (not shown) extending from the power module 902, for example, in a direction parallel to the substrate 906. For example, the power terminals 914 provide an electrical connection for power output from the power module 902. In such implementations, the power module 902 can provide power regulation, switching, phase inversion, and other power control or conditioning functions.

In some implementations, the semiconductor package assembly includes a second semiconductor die 950 mounted on the substrate 906. The semiconductor die 948 and the semiconductor die 950 are power switching devices arranged as a half bridge circuit providing high side switching and low side switching.

The power module 902 also includes molding material 916 encapsulating or partially encapsulating the components of the power module 902. For example, as shown in FIG. 9, the molding material 916 encapsulates the semiconductor die 948 and metal layer 934 of the substrate 906, while the molding material 916 partially encapsulates the substrate 906, the signal pins 912, and the power terminals 914. The bottom metal layer 936 (surface SS1) of the substrate 906 is exposed through the molding material 916, while the signal pins 912 extend through the molding material 916. The molding material 916 can be an epoxy molding compound, a resin molding compound, a gel molding compound, and so on. Though not specifically shown in FIG. 9, in some implementations, other elements can be included in the power module 902.

In some implementations, the power module 902 is bonded to the cooler 904, where the bottom metal layer 936 is bonded to a surface of the cooler 904. In some implementations, the bottom metal layer 936 and the cooler 904 are bonded using a thermal conductive adhesive material 938. In these implementations, such a conductive adhesive material can be a solder material, a sintering material (e.g., silver or copper), an epoxy material (e.g., silver filled epoxy), or a plating material (e.g., a tin plating material). In some implementations, the power module 902 is mechanically coupled to the cooler 904. For example, the power module 902 can be coupled to the cooler 904 via mechanical fasteners such as screws, clamps, nut-and-bolts, and the like. In some implementations, the power module 902 is both bonded and mechanically fastened to the cooler. For example, the semiconductor package can be sintered to the cooler 904 and screwed or clamped to the cooler 904.

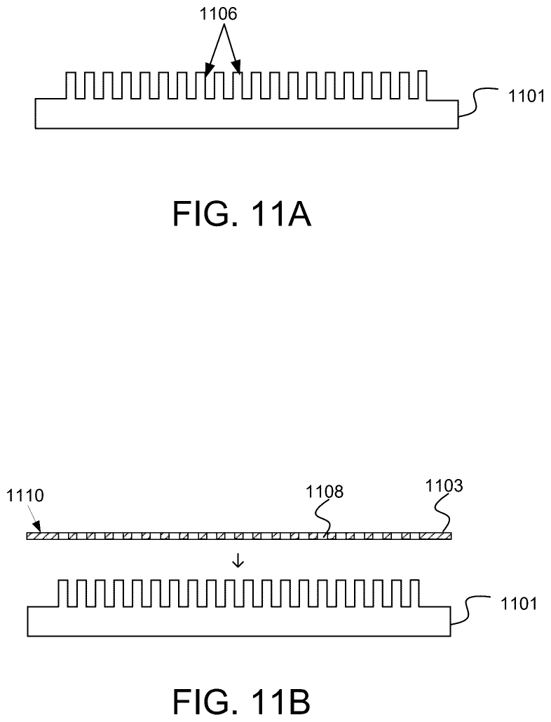

For further explanation, FIGS. 10A-10C set forth an example process of fabricating a heat dissipation device including a dual-coupled fin array in accordance with at least one embodiment of the present disclosure. Beginning with FIG. 10A, a bottom plate 1001 having an array of integrally formed fins 1006 is provided. For example, the bottom plate 1001 and the fins 1006 can be produced as a single piece, such as through extrusion, die casting, forging, or machining from a solid block (e.g., milling or CNC). As a result, each fin 1006 is continuous with the bottom plate 1001 and lacks any joint, seam, bond line, or interface that might otherwise occur if the fins 1006 were separately attached. For example, the bottom plate 1001 can correspond to the bottom plate 201 of FIG. 2 or the bottom plate 401 of FIG. 4.

In FIG. 10B, a top plate 1003 is mounted on the array of fins 1006. For example, the top plate 1003 can correspond to the top plate 203 of FIG. 2. In FIG. 10C, the fins 1006 are metallurgically bonded to a bottom surface of the top plate 1003. In various examples, the fins 1006 are metallurgically bonded via brazing or welding.

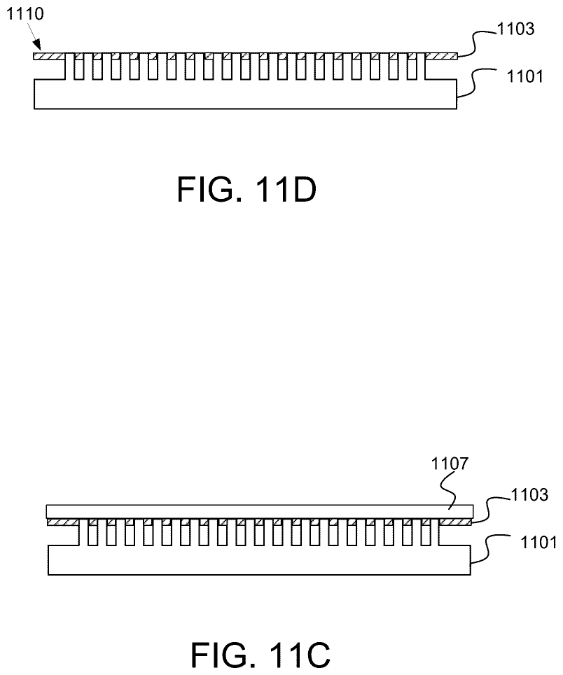

For further explanation, FIGS. 11A-11D set forth another example process of fabricating a heat dissipation device including a dual-coupled fin array in accordance with at least one embodiment of the present disclosure. Beginning with FIG. 11A, a bottom plate 1101 having an array of integrally formed fins 1106 is provided. For example, the bottom plate 1101 and the fins 1106 can be produced as a single piece, such as through extrusion, die casting, forging, or machining from a solid block (e.g., milling or CNC).

In FIG. 11B, a top plate 1103 is provided. The top plate 1103 includes an array of recesses 1108, which can be cavities or through-holes as discussed above. For example, the top plate 1003 can correspond to the top plate 403 of FIG. 4.

In FIG. 11C, the top plate 1103 is mounted on the array of fins 1106. The top plate 1103 is disposed on the fins 1106 such that the fins 1106 mate with the recesses 1108 and are inserted at least partially into the recesses 1108. For example, the top plate 1103 can be configured with recesses as depicted in FIG. 7. In some implementations, the recesses 1108 are through-holes such that the top surfaces of the fins 1106 are exposed on a top surface 1110 of the top plate 1103. The top surfaces of the fins 1106 can be coplanar with the top surface 1110 of the top plate 1103, or may be recessed relative to the top surface 1110.

In FIG. 11D, a cover plate 1107 is coupled to the top plate 1103. In some examples, the cover plate 1107 is coupled to the top surface 1110 of the top plate and the top surfaces of the fins 1106 that are exposed through the top plate 1103. In some examples, the cover plate 1107 is coupled via brazing. In such examples, a layer of brazing material can be applied to the top surface 1110 of the top plate 1103 and to the top surfaces of the fins 1106, if exposed. The cover plate 1107 is then metallurgically bonded to the top plate 1103 and top surfaces of the fins 1106 via a brazing process, such as the brazing processes discussed above.

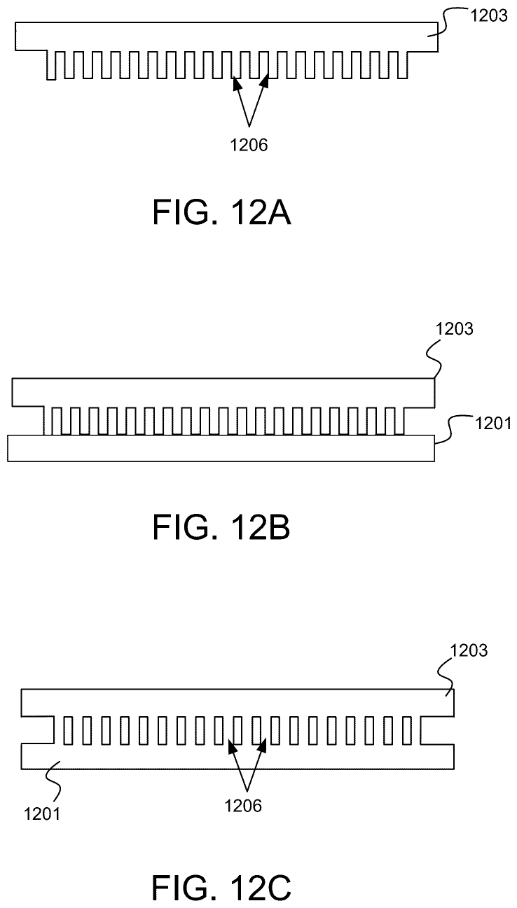

For further explanation, FIGS. 12A-12C set forth another example process of fabricating a heat dissipation device including a dual-coupled fin array in accordance with at least one embodiment of the present disclosure. Beginning with FIG. 12A, a top plate 1203 having an array of integrally formed fins 1206 is provided. For example, the top plate 1203 and the fins 1206 can be produced as a single piece, such as through extrusion, die casting, forging, or machining from a solid block (e.g., milling or CNC). As a result, each fin 1206 is continuous with the top plate 1203 and lacks any joint, seam, bond line, or interface that might otherwise occur if the fins 1206 were separately attached. For example, the top plate 1203 can correspond to the top plate 303 of FIG. 3 or the top plate 503 of FIG. 5.

In FIG. 12B, the array of fins 1206 is disposed on a bottom plate 1201. For example, the bottom plate 1201 can correspond to the bottom plate 301 of FIG. 3 or the bottom plate 501 of FIG. 5. In FIG. 12C, the fins 1206 are metallurgically bonded to a top surface of the bottom plate 1201. In various examples, the fins 1206 are metallurgically bonded via brazing or welding.

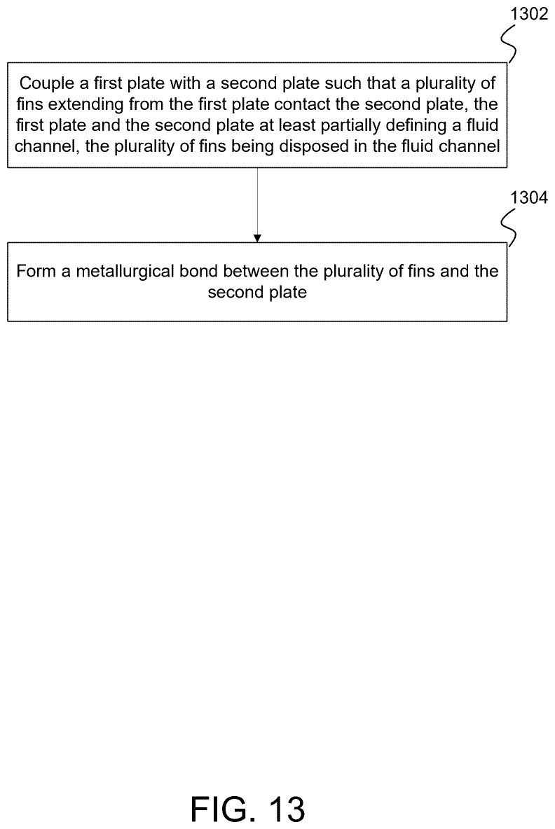

FIG. 13 is a flowchart of an example method for fabricating a heat dissipation device, such as the coolers described herein. The method begins at step 1302, which includes coupling a first plate with a second plate such that a plurality of fins extending from the first plate contact the second plate. The first and second plates at least partially define a fluid channel in which the fins are disposed. In some examples, the first plate is a bottom plate with integrally formed fins, and the second plate is a top plate, for example, as shown in FIGS. 2 and 4. In other examples, the first plate is a top plate with integrally formed fins, and the second plate is a bottom plate, for example, as shown in FIGS. 3 and 5. In some implementations, the coupling can involve mating the plurality of fins with a plurality of recesses in the second plate. For example, the fins can be inserted into through-holes in the second plate, as shown in the process of FIGS. 11A-11C. In other examples, the fins are inserted into cavities formed in a surface of the second plate, as depicted in FIG. 5. Alternatively, the fins can directly contact a surface of the second plate without recesses, as shown in FIGS. 2 and 3.

At step 1304, a metallurgical bond is formed between the plurality of fins and the second plate. This mechanically joins the first and second plates via the fin structure, increasing the rigidity of the heat dissipation device. In some examples, forming the metallurgical bond includes brazing the plurality of fins to the second plate. This can involve applying a brazing material (e.g., as a paste, preform, or clad layer) to the interface and heating the assembly to melt the brazing material, which then solidifies to form strong joints. In other examples, forming the metallurgical bond includes welding the plurality of fins to the second plate using a process such as laser welding, resistance welding, or electron-beam welding to fuse the fins to the plate. In implementations where the second plate includes through-holes, the method can further include disposing a cover plate on the second plate and forming a metallurgical bond between the cover plate, the second plate, and the respective top surfaces of the fins, as shown in FIG. 11D.

The heat dissipation device described herein offers significant advantages in structural rigidity and thermal performance. By mechanically joining the first and second plates with a plurality of fins, the overall structure acts as a unified, reinforced assembly. The formation of metallurgical bonds, such as braze or weld joints, between the fins and the opposing plate creates a continuous, high-strength connection that greatly enhances the cooler's resistance to bending and deflection. Furthermore, in implementations where the fins mate with corresponding recesses in the opposing plate, the movement of the fins is mechanically restricted, further stiffening the assembly. This metallurgical bonding and/or mechanical interlocking effectively mitigates warpage induced by thermal cycling, thereby preserving the integrity of the bond joint with an attached semiconductor device and ensuring reliable long-term operation.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

In some implementations, the direct bonded metal (DBM) substrate (e.g., direct bonded copper (DBC)) can include an insulating layer disposed between a first metal layer and a second metal layer. The insulating layer can be, for example, a ceramic layer. In some implementations, the insulating layer can be or can include, for example, a ceramic material such as alumina (Al2O3) or aluminum nitride (AlN)).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, the DBM substrate can be, or can include, a direct bonded copper (DBC) substrate (e.g., a DBM with copper metal layers). In some implementations, such as in DBC substrate implementations, the first metal layer and/or the second metal layer is a copper layer.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wirebonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

The semiconductor device packages described herein can include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package. In some implementations, one or more portions of a leadframe can be coupled to a pad (e.g., a bond pad) on at least a portion of a DBM substrate.

In some implementations, a molding compound (e.g., molding material or compound, an encapsulation material) can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die associated with the implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a module (e.g., a package including a semiconductor device) can be included in another module. The module can be referred to as a package. For example, one or more modules can be one or more sub modules included within another module. In other words, a first module can be included as a sub module within a second module.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A heat dissipation device comprising:
a first plate;
a second plate;
a fluid channel defined at least in part by the first plate and the second plate; and
a plurality of fins disposed in the fluid channel, the plurality of fins mechanically joining the first plate to the second plate.

2. The heat dissipation device of claim 1, wherein the plurality of fins extend from a surface of the first plate, the heat dissipation device further comprising a plurality of metallurgical joints respectively joining the plurality of fins to the second plate.

3. The heat dissipation device of claim 2, wherein the plurality of metallurgical joints is one of a plurality of braze joints or a plurality of weld joints.

4. The heat dissipation device of claim 2, wherein the plurality of fins and the first plate are integrally formed.

5. The heat dissipation device of claim 1, wherein the second plate includes plurality of recesses, the plurality of recesses corresponding with the plurality of fins, the plurality of fins being inserted in the plurality of recesses.

6. The heat dissipation device of claim 5, wherein the plurality of recesses is a plurality of through-holes.

7. The heat dissipation device of claim 6 further comprising:
a cover plate joined to the first plate.

8. The heat dissipation device of claim 1, further comprising an inlet port and an outlet port coupled to the fluid channel, the inlet port and the outlet port disposed at opposite sides of the heat dissipation device.

9. The heat dissipation device of claim 1, further comprising an inlet port and an outlet port coupled to the fluid channel, the inlet port and the outlet port disposed on a bottom surface of the second plate.

10. A heat dissipation device comprising:
a first plate including a plurality of recesses;
a second plate including a plurality of fins extending from the second plate and mating with the plurality of recesses; and
a fluid channel defined at least in part by the first plate and the second plate, the plurality of fins disposed in the fluid channel.

11. The heat dissipation device of claim 10 further comprising a plurality of metallurgical joints that respectively join the plurality of fins to the second plate, the plurality of metallurgical joints being one of a plurality of braze joints or a plurality of weld joints.

12. The heat dissipation device of claim 10, wherein the first plate is a top plate and the second plate is a bottom plate, the plurality of fins being integrally formed with the bottom plate.

13. The heat dissipation device of claim 12, wherein the plurality of recesses is a plurality of a through-holes.

14. The heat dissipation device of claim 13, wherein top surfaces of the plurality of fins are coplanar with a surface of the top plate.

15. The heat dissipation device of claim 13 further comprising a cover plate coupled to the top plate, the cover plate being configured for attachment to a power module.

16. The heat dissipation device of claim 10, wherein the first plate is a bottom plate and the second plate is a top plate, the plurality of fins being integrally formed with the top plate.

17. The heat dissipation device of claim 16, wherein the plurality of recesses is a plurality of cavities in a surface of the bottom plate within the fluid channel.

18. A method comprising:
coupling a first plate with a second plate such that a plurality of fins extending from the first plate contact the second plate, the first plate and the second plate at least partially defining a fluid channel, the plurality of fins being disposed in the fluid channel; and
forming a metallurgical bond between the plurality of fins and the second plate.

19. The method of claim 18, wherein forming the metallurgical bond includes:
brazing plurality of fins to the second plate.

20. The method of claim 18, wherein forming the metallurgical bond includes:
welding plurality of fins to the second plate.

21. The method of claim 18, wherein coupling the first plate with the second plate includes:
mating the plurality of fins with a plurality of recesses in the second plate.

22. The method of claim 21, wherein the plurality of recesses is a plurality of through-holes, the method further comprising:
disposing a cover plate on the second plate; and
forming a metallurgical bond between the cover plate and the second plate and between the cover plate and respective top surfaces of the plurality of fins.
